(19) United States
(12) Patent Application Publication
(10) Pub. No.: US 2006/0138312 A1
(43) Pub. Date: Jun. 29, 2006

(54) Solid-state spectrophotomer

(76) Inventors: Mark Melvin Butterworth, Santa Clara, CA (US); Jeremy Alfred Theil, Mountain View, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/021,079

(22) Filed: Dec. 22, 2004

(51) Int. Cl. G01J 3/50; H01L 31/00; H01J 40/14; H01J 5/16

(52) U.S. Cl. 250/226; 250/214.1

(57) ABSTRACT

In accordance with an embodiment of the present invention, a spectrophotomer includes a plurality of photon detection regions and a photon absorption material. The photon absorption material is placed above the plurality of photon detection regions. Thickness of the photon absorption material above each of the photon detection regions in the plurality of photon detection region is varied to vary a spectrum of light wavelengths detected by each photon detection region in the plurality of photon detection regions.

### BACKGROUND

A spectrophotomer is an instrument used to measure the intensity of wavelengths in a spectrum of light. In one type of spectrophotomer, a sample beam is directed through a sample chamber and measured against a reference beam at each wavelength of the spectrum. This allows creation of a plot that shows intensity of light verses light wavelength.

Solid-state photon detectors typically are implemented using photodiodes or phototransistors. Photons impinging upon photon detectors are absorbed by a photon detection region of the photon detector. The depth at which photons are absorbed within the photon detection region depend upon the wavelength of the photon. Longer wavelengths result in a greater depth of absorption. Shorter wavelengths result in shorter depths of absorption.

### SUMMARY OF THE INVENTION

In accordance with an embodiment of the present invention, a spectrophotomer includes a plurality of photon detection regions and a photon absorption material. The photon absorption material is placed above the plurality of photon detection regions. Thickness of the photon absorption material above each of the photon detection regions in the plurality of photon detection region is varied to vary a spectrum of light wavelengths detected by each photon detection region in the plurality of photon detection regions.

### BRIEF DESCRIPTION OF THE DRAWINGS

FIG. 1 is a simplified diagram illustrating implementation of a spectrophotomer in accordance with an embodiment of the present invention.

FIG. 2 show a sample solid-state photon detector which can be used to implement a solid-state spectrophotomer in accordance with an embodiment of the present invention.

### DESCRIPTION OF THE EMBODIMENT

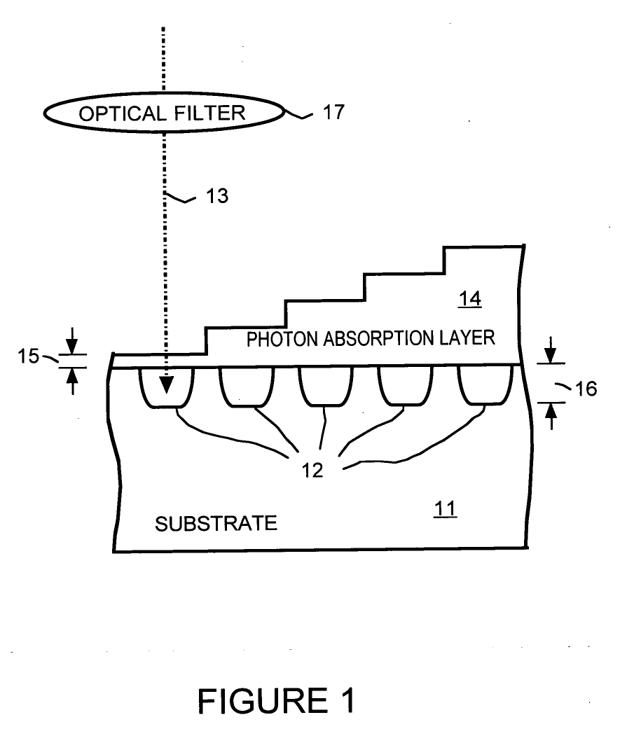

FIG. 1 is a simplified block diagram illustrating implementation of a spectrophotometer. Within or upon a substrate 11 are formed photon detection regions 12 for photon detectors. For example, the photon detectors are photodiodes or phototransistors. For example, substrate 11 is composed of silicon.

Photon absorption material 14 is placed above photon detection regions 12. Each of photon detection regions 12 is part of a separate photon detector. While FIG. 1 shows five photon detection regions, this is only exemplary. The number of photon detection regions depends, for example, upon the resolution desired for a particular implementation. Size of photon detection regions 12 is not to scale.

For example, photon absorption material 14 includes a layer of amorphous silicon of varying thickness. Photons impinging upon photon absorption material 14 are absorbed depending upon the wavelength of the photon and the thickness of photon absorption material 14. Photons with longer wavelengths pass through photon absorption material 14 without being absorbed. The length of the wavelength at which photons are not absorbed by photon absorption material 14 depends upon the thickness of photon absorption material 14 at which the photon impinges photon absorption material 14. At portions of photon absorption material 14 that are relatively thick, only photons with relatively large wavelength are able to pass through without being absorbed. At portions of photon absorption material 14 that are relatively thin, photons with a larger spectrum of wavelengths are able to pass through without being absorbed. Thus varying the thickness of photon absorption material 14 varies the minimum wavelength required for photons to pass through photon absorption material 14 without being absorbed.

Photons that pass through photon absorption material 14 are absorbed by photon detection regions 12 or by other portions of substrate 11. Those photons that impinge upon photon detection regions 12 are absorbed by photon detection regions 12 depending upon the wavelength of the photon and the thickness of photon regions 12. Photons with longer wavelengths pass through photon detection regions 12 without being absorbed. The length of the wavelength at which photons are not absorbed by photon detection regions 12 depends upon the combined thickness of photon detection regions 12 and the thickness of photon absorption material 14 at which the photon impinges photon absorption material 14.

Varying the thickness of photon absorption material 14 over each photon detection region 12, results in varying the spectrum of light wavelengths absorbed by each photon detection region. The thickness of photon absorption material 14 over a photon detection region controls the minimum wavelength of photons that can be detected by the photon detection region. The thickness of the photon detection region controls the size of the wavelength spectrum of light detected by the photon detection region. In effect, by varying the thickness of photon absorption material 14 and/or photon detection regions 12, resulting bandpass filters can be tuned to allow detection of light intensity at different wavelengths. This allows solid-state implementation of a spectrophotomer.

For example, when implementing a spectrophotomer, a thickness 16 of photon detection regions 12 is uniform for all photon detection regions 12. A thickness 15 of photon absorption material 14 is varied during processing. For example, after formation of an amorphous silicon layer, the amorphous silicon layer is etched using binary etch processing steps. When binary etch processing steps are used, x etch processing steps can be used to form 2^{X} levels of thickness. Thus three etch processing steps can result in 8 levels of thickness. Eight etch processing steps can be used to create 256 levels of thickness. Using currently available processing technology, silicon absorbs light with wavelengths from about 350 nanometers to 1100 nanometers. By selecting the number of etching steps, it is possible to determine the available resolution of the spectrophotomer.

FIG. 1 shows an optional optical filter 17 that can be used to add additional selectivity to the measurement range of the spectrophotomer. Optional optical filter 17 modifies a light beam 13 before light beam 13 reaches photon absorption material 14. For example optional optical filter 17 is a low pass filter, a high pass filter, a bandpass filter or a notch filter.

While in FIG. 1 thickness of photon absorption material 14 is varied in order to vary the wavelength of light absorbed by photon absorption material 14, the wavelength of light absorbed by photon absorption material 14 can be varied in other ways. For example, varying the composition of photon absorption material 14 can also result in varying the wavelength of light absorbed by photon absorption material 14 at different locations.

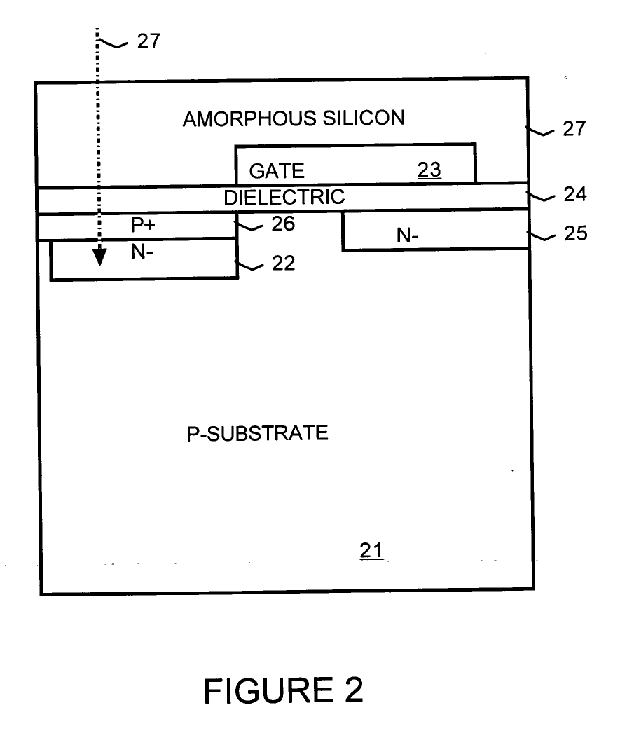

As discussed above, any known type of photodiode, photon detector or other form of solid-state photon detector can be used to implement a spectrophotomer as disclosed above. For example, FIG. 2 shows a simplified diagram of a photon detector implemented in a charge coupled device. An n-region 22 within p substrate 21 acts as a detection region. The thickness of the photon absorption material is essentially the thickness of amorphous silicon 27, dielectric 24 (if not transparent) and p+ regions 26 at the location directly over n-region 22. The thickness of n-region 22 determines the size of the wavelength spectrum of light absorbed by n-region 22. Photons from a light beam 28 that are absorbed by n-region 22 result in formation of electrons. The electrons are subsequently transferred into an n-region 25 when a voltage is applied to a gate 23. P+ region 26 helps to control the voltage in n-region 22.

The photon detector shown in FIG. 2 is merely illustrative. Active pixel sensors and all other types of photodiodes, phototransistors and photon detectors can also be used to implement the spectrophotomer disclosed herein. The foregoing discussion discloses and describes merely exemplary methods and embodiments of the present invention. As will be understood by those familiar with the art, the invention may be embodied in other specific forms without departing from the spirit or essential characteristics thereof. Accordingly, the disclosure of the present invention is intended to be illustrative, but not limiting, of the scope of the invention, which is set forth in the following claims.

1. A spectrophotomer comprising;
a plurality of photon detection regions; and,
a layer of photon absorption material formed directly over the plurality of photon detection regions, thickness of the layer of photon absorption material above each of the photon detection regions in the plurality of photon detection region being varied to vary a spectrum of light wavelengths detected by each photon detection region in the plurality of photon detection regions.

2. A spectrophotomer as in claim 1 wherein the photon detection regions are located within a silicon substrate.

3. A spectrophotomer as in claim 1 wherein all the photon detection regions within the plurality of photon detection regions have a same thickness.

4. A spectrophotomer as in claim 1 wherein the photon absorption material includes amorphous silicon.

5. A spectrophotomer as in claim 1 wherein the photon absorption material includes amorphous silicon that has been etched using binary etch processing steps.

6. A spectrophotomer as in claim 1 wherein the plurality of photon detection regions are within one of:
a plurality of photodiodes;
a plurality of phototransistors.

7. A spectrophotomer as in claim 1 additionally comprising an optical filter used to add additional selectivity to a measurement range of the spectrophotomer.

8. A spectrophotomer as in claim 1 additionally comprising an optical filter used to add additional selectivity to a measurement range of the spectrophotomer, the optical filter being one of the following:
a low pass filter;
a high pass filter;
a bandpass filter;
a notch filter.

9. A device that detects intensity of light at different wavelengths, the device comprising:
a plurality of photon detectors, each photon detector having a photon detection region; and,
a layer of photon absorption material formed directly over the photon detection regions, a property of the layer of photon absorption material above each of the photon detection regions being varied to vary a spectrum of light wavelengths detected by each photon detection region in the plurality of photon detection regions.

10. A device as in claim 9 wherein the photon detection regions are located within a silicon substrate.

11. A device as in claim 9 wherein all the photon detection regions have a same thickness.

12. A device as in claim 9 wherein the property of the layer of photon absorption material that is varied to vary a spectrum of light wavelengths detected by each photon detection region in the plurality of photon detection regions is thickness of the photon absorption material above each photon detection region.

13. A device as in claim 9 wherein the photon absorption material includes amorphous silicon that has been etched using binary etch processing steps.

14. A device as in claim 9 wherein the plurality of photon detectors are one of following:
a plurality of photodiodes;
a plurality of phototransistors.

15. A device as in claim 9 additionally comprising an optical filter used to add additional selectivity to a measurement range of the device.

16. A device as in claim 9 additionally comprising an optical filter used to add additional selectivity to a measurement range of the device, the optical filter being one of the following:
a low pass filter;
a high pass filter;
a bandpass filter;
a notch filter.

17. A method for producing a device that detects intensity of light at different wavelengths comprising:
forming a plurality of photon detection regions; and,
forming a layer of photon absorption material directly over the plurality of photon detection regions, a property of the layer of photon absorption material above each of the photon detection regions in the plurality of photon detection region being varied to vary a spectrum of light wavelengths detected by each photon detection region in the plurality of photon detection regions.

18. A method as in claim 17 wherein the photon detection regions are formed within a silicon substrate.

19. A method as in claim 17 wherein the absorption material includes amorphous silicon.

20. A method as in claim 17 wherein forming the layer of photon absorption material over the plurality of photon detection regions includes:
forming a layer of amorphous silicon over the photon detection regions; and,
performing binary etch processing steps of the layer of amorphous silicon to vary thickness of the layer of amorphous silicon over each of the plurality of photon detection regions.
